(19) United States
(12) Patent Application Publication
(10) Pub. No.: US 2024/0300808 A1
(43) Pub. Date: Sep. 12, 2024

(54) MEMS STRESS ISOLATION TECHNOLOGY WITH BACKSIDE ETCHED ISOLATION TRENCHES

(71) Applicant: Analog Devices, Inc., Wilmington, MA (US)

(72) Inventors: Kemiao Jia, Tolland, CT (US); Gaurav Vohra, Sudbury, MA (US); Xin Zhang, Acton, MA (US); Christine H. Tsau, Belmont, MA (US); Chen Yang, Lexington, MA (US); Andrew Proudman, Stoneham, MA (US); Matthew Kent Emsley, North Reading, MA (US); George M. Molnar, II, Westford, MA (US); Nikolay Pokrovskiy, Billerica, MA (US); Ali Mohammed Shakir, Andover, MA (US); Michael Judy, Ipswich, MA (US)

(73) Assignee: Analog Devices, Inc., Wilmington, MA (US)

(21) Appl. No.: 18/596,223

(22) Filed: Mar. 5, 2024

Related U.S. Application Data
(60) Provisional application No. 63/450,197, filed on Mar. 6, 2023.

(51) Int. Cl. B81C 1/00; B81B 3/00

(52) U.S. Cl. CPC B81C 1/00666; B81B 3/0072; B81B 2203/0118; B81B 2203/0307; B81B 2203/0315; B81C 2201/0111; B81C 2201/019

(57) ABSTRACT

Described herein are manufacturing techniques for achieving stress isolation in microelectromechanical systems (MEMS) devices that involve isolation trenches formed from the backside of the substrate. The techniques described herein involve etching a trench in the bottom side of the substrate subsequent to forming a MEMS platform, and processing the MEMS platform to form a MEMS device on the top side of the substrate subsequent to etching the trench.

### CROSS-REFERENCE TO RELATED APPLICATIONS

This application claims the benefit under 35 U.S.C. § 119(c) of U.S. Provisional Application Ser. No. 63/450,197, filed on Mar. 6, 2023, under Attorney Docket No. G0766.70358US00, and entitled “MEMS STRESS ISOLATION TECHNOLOGY WITH BACKSIDE ETCHED ISOLATION TRENCHES,” which is hereby incorporated herein by reference in its entirety.

### FIELD OF THE DISCLOSURE

The present disclosure relates to stress-sensitive micro-scale devices, such as sensors.

### BACKGROUND

There are various types of microelectromechanical systems (MEMS) devices. Some MEMS devices comprise sensors, for example, gyroscopes, accelerometers, or pressure sensors. MEMS devices may be sensitive to stress. For example, when there is a stress in a substrate upon which a MEMS sensor is disposed, the MEMS sensor may provide different performance and/or output than if there was not a stress in the substrate.

### SUMMARY OF THE DISCLOSURE

Some embodiments relate to a method for manufacturing of a stress-isolated MEMS device. The method may comprise providing a substrate having a first side and a second side opposite the first side, forming a MEMS platform on the first side of the substrate, subsequent to forming the MEMS platform, etching a trench in the second side of the substrate, and subsequent to etching the trench, processing the MEMS platform to form a MEMS structure on the first side of the substrate.

Some embodiments relate to a method for manufacturing a stress-isolated device. The method may comprise providing a substrate having a first side and a second side opposite the first side, forming a precursor of a microelectromechanical systems (MEMS) device on the first side of the substrate, the precursor including at least one MEMS structure, subsequent to forming the precursor of the MEMS device, etching a trench in the second side of the substrate, and subsequent to etching the trench, processing the at least one MEMS structure to form a MEMS device, from the precursor, on the first side of the substrate.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 shows a process flow of a method of manufacture of a stress-isolated MEMS device.

FIGS. 2A-2G show cross-sectional views of steps of a manufacturing process of a stress-isolated MEMS device.

FIG. 2H shows a top view of a portion of a stress-isolated MEMS device.

### DETAILED DESCRIPTION

Aspects of the present disclosure relate to manufacturing techniques for achieving stress isolation in microelectromechanical systems (MEMS) devices that involve isolation trenches formed from the backside of the substrate.

Compared to other previous manufacturing techniques, such as for front side trenches, the approach described herein is less complex, easier to manufacture, and is less susceptible to the issues arising in previous implementations, some of which are discussed below. Backside trenches provide several benefits over front side trenches. Some of the approaches for forming frontside trenches involve the steps of refilling the front side trenches with polysilicon (also referred to herein as “poly”), and subsequently the step of removing the polysilicon. The inventors have appreciated that these steps render the fabrication process overly complex from a manufacturing standpoint and lead to undesired features appearing in the bottom capping substrate (the “bottom cap”). For example, the polysilicon etch step may unintentionally create over etch grooves in the bottom cap.

Further, the conventional approach requires the step of etching the structural beam to expose the trench polysilicon, and the step of protecting the structural beam (also referred to as the “MEMS beam” or simply the “beam”) with photoresist during the trench polysilicon etch. The inventors have further appreciated that these process steps set an upper limit to the thickness of the structural beam. In some implementations, for example, the thickness of the structural beam is limited to 16 μm. The limited thickness can negatively affect the performance of a MEMS device.

The techniques described herein—involving etching isolation trenches from the backside of a substrate—present several advantages over previous implementations that rely on front side etching. The advantages include omitting the step of refilling the front side trenches with polysilicon and the subsequent step of removing the polysilicon to release the trenches, thereby simplifying the manufacturing process, making it less costly, and preventing the formation of over etch grooves in the bottom cap, which may otherwise lead to breakage during wafer handling. Also, without the need to protect the etched structural beam, thicker structural beams (e.g., greater than 16 μm) can be achieved.

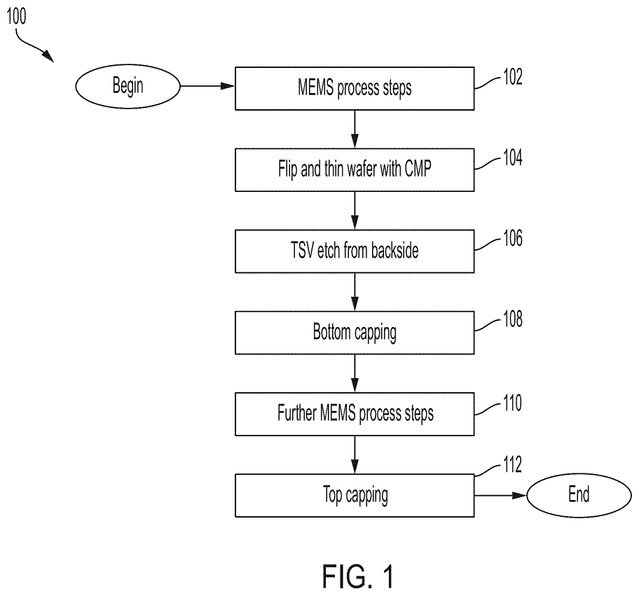

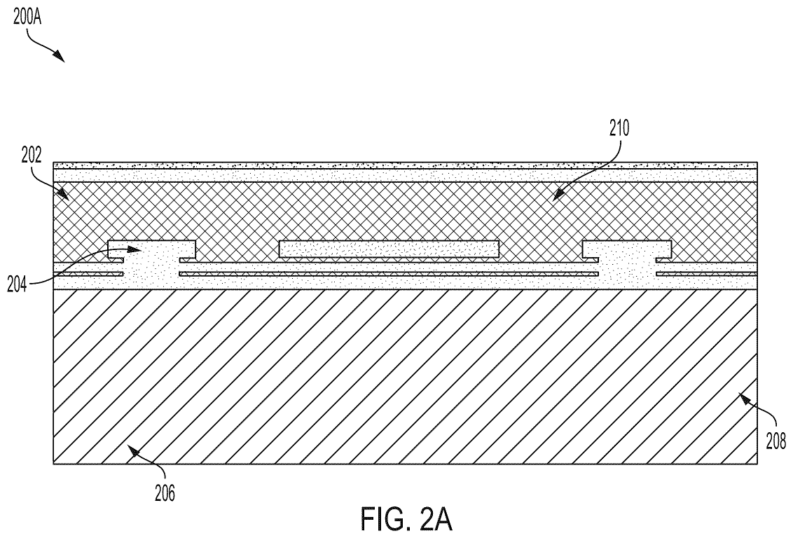

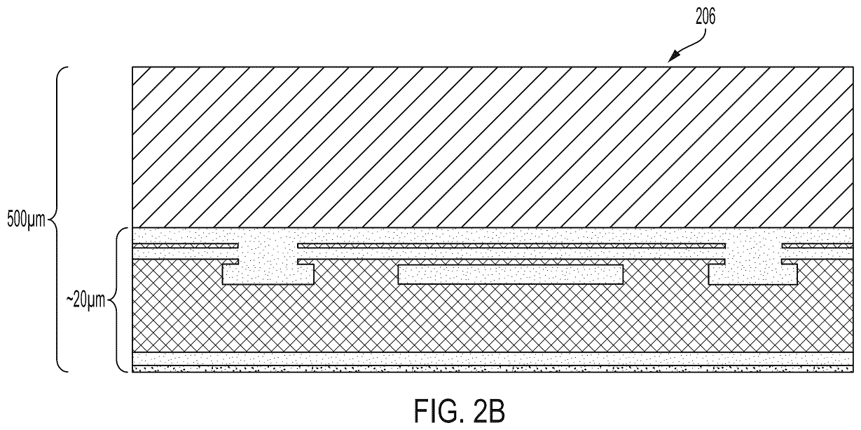

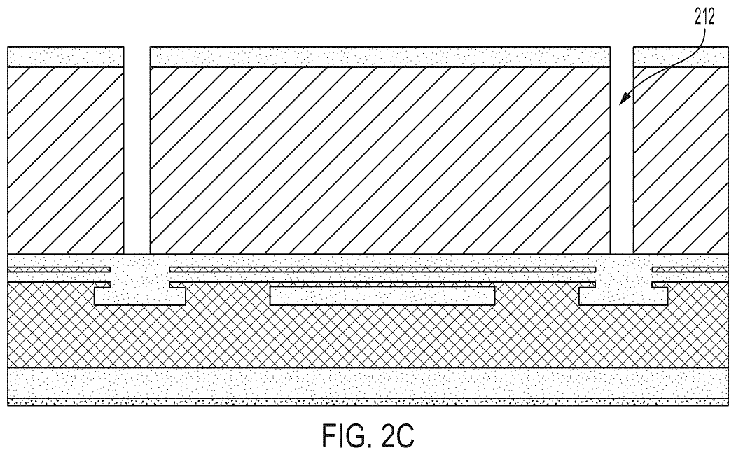

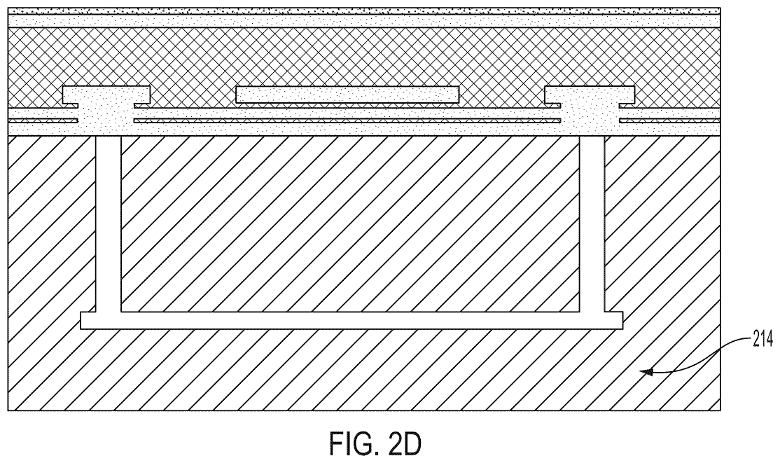

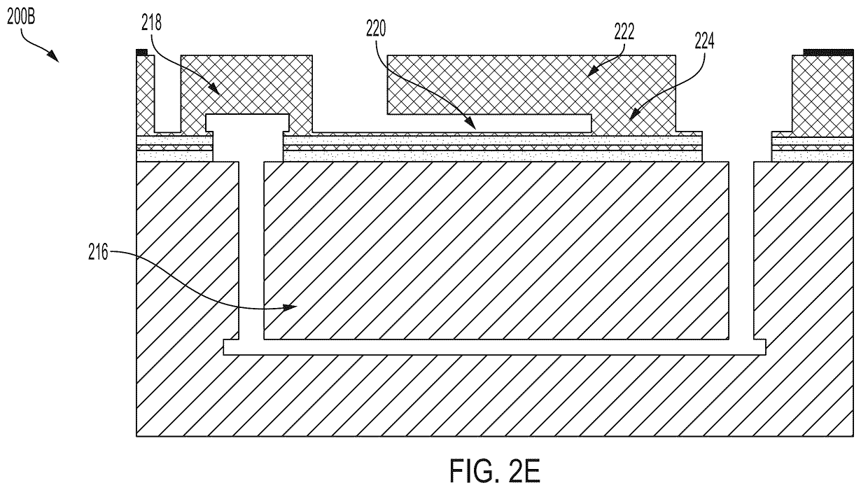

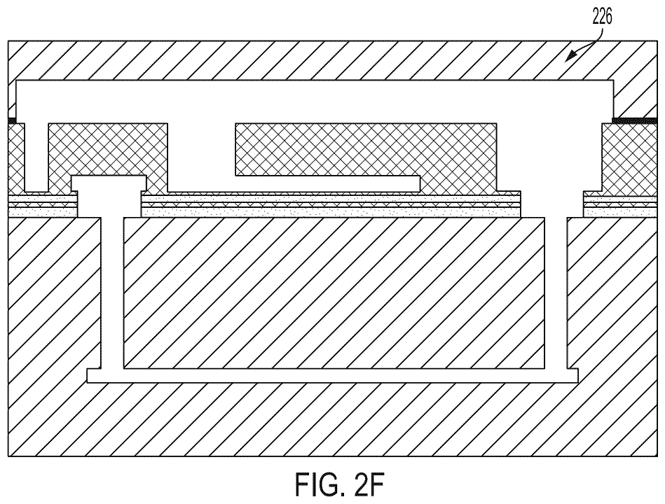

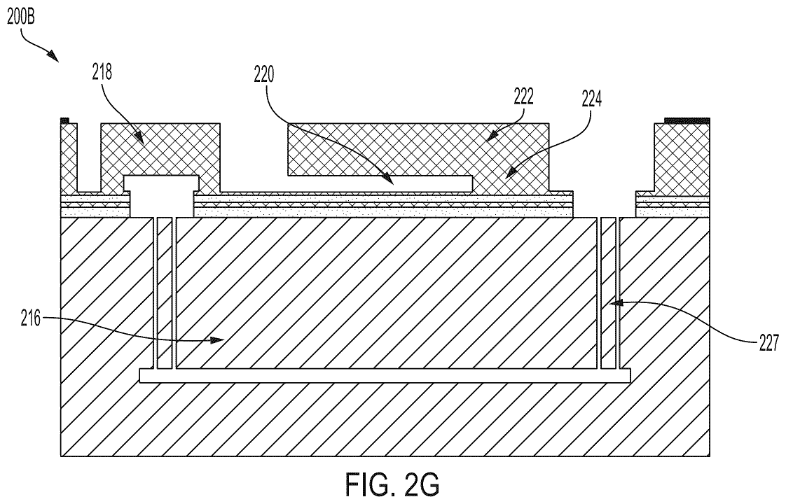

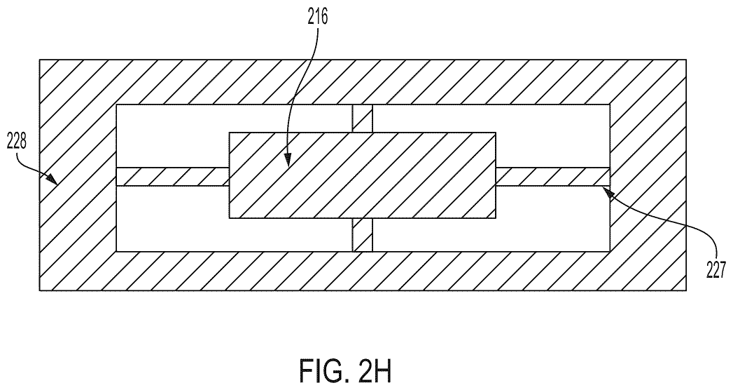

FIG. 1 shows a process flow 100 of a method of manufacture of a stress-isolated MEMS device. The steps of FIG. 1 may correspond to the processing steps shown in FIGS. 2A-2G. In some embodiments, the steps of FIG. 1 may correspond to other steps. While the steps performed as part of the method may be ordered in any suitable way, the inventors have recognized that the process flow and processing steps as described herein may provide various benefits.

FIGS. 2A-2G illustrate processing steps for fabricating a MEMS device with stress isolation. In this process flow, isolation trenches are formed from the backside of the substrate. First, a MEMS process step is performed to form one or more partially formed MEMS devices. Then, the wafer is flipped, and optionally the backside is thinned. In one example, the resulting structural beam is thicker than 16 μm (e.g., 20 μm), and the substrate is 500 μm thick or less. Then, isolation trenches are etched through the backside of the substrate. Subsequently, a bottom cap is formed, and further MEMS process steps are performed to fully form the MEMS device(s). Lastly, a top cap is formed.

Referring to FIG. 1, at step 102, MEMS process steps are performed, for example, as shown in and described in relation to FIG. 2A. The MEMS process steps of FIG. 1 may include forming a MEMS platform on a first side of a substrate, such as a front side. Forming a MEMS platform may include fabricating a partially formed MEMS device. At this stage, the MEMS device may be partially formed in that suspended proof masses have not been released yet (though they will ultimately be released after the formation of backside trenches). In some embodiments, a precursor of a MEMS device is formed on the first side of the substrate, and the precursor may include at least one MEMS structure. The term “precursor” indicates that a MEMS device has been formed, but has not been released yet. As described in detail below, a release step generates a fully formed MEMS device from a MEMS precursor.

Referring to FIG. 2A, a MEMS device 200A is shown, and the MEMS device may include a wafer 208 that may be oriented on a surface (not shown). The wafer is an example of a substrate. The substrate may have a first side and a second side opposite the first side (e.g., the frontside and the backside, respectively). The wafer 208 may have a backside 206 as shown in FIG. 2A. The substrate may be provided as part of the process steps.

A MEMS platform 210 may be formed on wafer 208. The MEMS platform 210 may include a partially formed MEMS device. The partially formed MEMS device may include MEMS structures, such that, in some embodiments, the MEMS platform includes MEMS structures on a top side.

In some embodiments, at this stage, the MEMS structures may include anchors, electrodes, beams, precursor of a formed proof mass, and other structures, as the techniques are not so limited. As an example, the MEMS platform may include a proof mass that is attached to the underlying substrate, such as wafer 208 shown in FIG. 2A. The proof mass may become a suspended proof mass as a result of MEMS processing (e.g., as described in relation to step 110 of FIG. 1). By including MEMS structures with the MEMS platform at step 102 (e.g., as shown in FIG. 2A), the MEMS structures can be added to the MEMS device on a flat surface. An anchor may also be formed as part of step 102, in some embodiments. Such an anchor may be arranged to support a suspended, movable proof mass above the substrate when the proof mass is released in the following steps.

The MEMS platform 201 may include polysilicon 202 (although this layer may be made of silicon, silicon carbide, aluminum nitride, or metal) and oxide 204 (although this sacrificial layer may be made of other materials, such as silicon nitride). The MEMS platform may include other suitable materials, as the techniques are not so limited.

At step 104, a wafer (e.g., wafer 208) is flipped and optionally may be thinned with chemical mechanical polishing (CMP), for example. In other embodiments, the thinning may be performed using techniques commonly used to reduce the thickness, such as etching. Referring to FIG. 2B, the backside 206 of the wafer 208 may be thinned and have a reduced thickness relative to the thickness of FIG. 2A. As an example, the thickness of the wafer 208 after thinning may be 480 micrometers (or microns). Thinning the second side of the substrate (e.g., backside 206) may occur prior to a step of etching a trench (e.g., as described in relation to step 106). The thinning may be performed prior to forming a MEMS device (e.g., as described in relation to step 110).

FIG. 2B shows example dimensions including a thickness of 500 micrometers for the MEMS device and 20 micrometers for the MEMS platform. While dimensions are provided, the dimensions are exemplary and, in some embodiments, the thickness of the MEMS device may be between approximately 100 micrometers and approximately 500 micrometers. In some embodiments, the thickness of the platform is between approximately 10 micrometers and approximately 50 micrometers. In some embodiments, the thickness of the platform is between approximately 50 micrometers and approximately 150 micrometers. In some embodiments, the thickness of the platform is between approximately 100 micrometers and approximately 500 micrometers.

At step 106, an etch is performed from the backside of the device (e.g., MEMS device 200A). The etch may be performed using techniques commonly used in semiconductor processing to form through silicon vias (TSV). Referring to FIG. 2C, a TSV etch 212 is shown. The TSV etch may result in the formation of a trench. The etching of a trench in the second side of the substrate (e.g., the backside) may be performed subsequent to forming the MEMS platform and/or the precursor of a MEMS device. The etching may include exposing a portion of the MEMS platform to air (or to a dielectric material, or a different environment containing fluid or solid materials). In FIG. 2C, two trench portions are shown. While the cross-section shown in FIG. 2C appears in two dimensions, the trench may extend in an additional dimension. As an example, the trench may encircle the surrounding layer, thereby mechanically isolating the MEMS platform from the remainder of the substrate and providing stress-free operation (or at least reducing stress).

At step 108, bottom capping may be performed. Bottom capping may involve bonding a cap to a layer of the device. Referring to FIG. 2D, a bottom cap 214 is coupled to the device. In some embodiments, the bottom cap 214 is bonded to bottom side of the wafer. The bonding may be silicon-to-silicon, silicon-to-oxide or silicon-to-metal, among other examples. Forming the bottom cap (e.g., on the second side of the substrate) may be performed subsequent to etching the trench, as shown by process flow 100 in FIG. 1. The formation of the bottom cap may be performed prior to processing the MEMS platform (e.g., prior to step 110 described herein). In some embodiments, the bottom capping may be formed with a coating intended to reduce the pressure of any residual gas that may otherwise be present within the MEMS cavity (to a level greater or less than the atmospheric pressure). The coating may be made of a material that absorbs gas. The coating may be formed on the side of the bottom capping that is exposed to the MEMS cavity. As described below, a similar coating may be formed on the top capping. Coating both caps can further reduce the pressure of the residual gas. The coating can be formed as part of the bonding process (e.g., silicon to silicon, silicon to oxide, or eutectic metal bonding between two silicon surfaces).

At step 110, further MEMS process steps may be performed. The further MEMS process steps may include releasing a precursor proof mass or releasing a layer. The further MEMS process steps may include patterning and/or etching techniques (e.g., including etching oxide positioned under a proof mass). The further MEMS process steps may result in a movable proof mass and/or movable beam. The processing may include processing the MEMS platform to form a MEMS device on the first side of the substrate (e.g., the front side) subsequent to etching the trench. Processing the MEMS platform may include forming a suspended proof mass (e.g., as described in relation to FIG. 2E). The further MEMS processing may include processing at least one MEMS structure to form a MEMS device, such as from the precursor, on the first side of the substrate. Processing the at least one MEMS structure may include etching a portion of the at least one MEMS structure to release one or more suspended proof masses.

In some embodiments, step 110 further includes releasing the isolated portions from the rest of the substrate. This may involve etching the oxide (or other sacrificial material) covering the isolation trenches. The result is that the isolation portion is mechanically disconnected from the substrate and is held by tethers only. Tethers 227 are illustrated in FIGS. 2G-2H, which are discussed further below.

Referring to FIG. 2E, a resulting device following the further MEMS process steps is shown. According to some embodiments, after step 110 is performed, a stress-isolated MEMS device 200B may be formed as shown in FIG. 2E. The stress-isolated device may include an isolated portion 216. A bridge 218 may be formed above the isolated portion 216 and may be coupled to the isolated portion 216. Bridge may couple the device to the rest of the substrate electrically. A recess 220 may be formed in the device. A suspended proof mass 222 may be formed as described herein. The recess 220 shown in FIG. 2E allows motion of the proof mass. An anchor 224 was formed as part of step 102, as discussed above. The anchor may be coupled to the suspended proof mass 222.

At step 112, top capping may be performed. Top capping may involve bonding a cap to a layer of the device. Referring to FIG. 2F, a top cap 226 may be formed on the device. Forming the top cap (e.g., on the first side of the substrate) may be performed subsequent to processing the MEMS platform and/or the at least one MEMS structure (e.g., as described in relation to step 110). In some embodiments, the top capping may be formed with a coating intended to reduce the pressure of any residual gas that may otherwise be present within the MEMS cavity. The coating may be made of a material that absorbs gas. The coating may be formed on the side of the top capping that is exposed to the MEMS cavity.

In some embodiments, tethers may be formed as part of the fabrication process discussed above. Tethers may be structures configured to mechanically couple the isolated portion 216 to the remainder of the substrate. The coupling may be elastic, thereby allowing the isolated portion 216 to move relative to the substrate. As such, the tethers may be viewed as springs.

FIG. 2G is similar to FIG. 2E, expect that a tether 227 is formed within the isolation trench. In this example, the trench is made of the same material as the substrate, and has the same height as the trench. However, not all embodiments are limited in this respect. For example, other materials may be used for the tethers. Additionally, or alternatively, the height of the tethers may be a fraction of the height of the trench.

The precursor of the tether may be formed as part of step 106. This is a precursor of the tether (as opposed to a fully formed tether) in that the tether has not been released yet. In the subsequent release (step 110), the residual material around the tether is etched and the tether is fully formed. FIG. 2H is a top view of the MEMS device of FIG. 2G illustrating the tethers. As shown, tethers 227 mechanically couple the isolated portion 216 to the remainder (228) of the substrate. It should be noted that the tethers may have different shapes relative to what is shown in FIG. 2H. Additionally, or alternatively, the tethers may be positioned at different locations around isolated portion 216 relative to what is shown and/or there may be a different number of tethers relative to what is shown in FIG. 2H. In one example, some (or all) the tethers may be shaped as multi-segment tethers.

What is claimed is:

1. A method for manufacturing of a stress-isolated microelectromechanical systems (MEMS) device, comprising:
providing a substrate having a first side and a second side opposite the first side;
forming a MEMS platform on the first side of the substrate;
subsequent to forming the MEMS platform, etching a trench in the second side of the substrate; and
subsequent to etching the trench, processing the MEMS platform to form a MEMS structure on the first side of the substrate.

2. The method of claim 1, further comprising thinning the second side of the substrate prior to etching the trench.

3. The method of claim 2, wherein thinning the second side of the substrate is performed prior to forming the MEMS structure.

4. The method of claim 1, further comprising forming a bottom cap on the second side of the substrate subsequent to etching the trench.

5. The method of claim 4, wherein forming the bottom cap is performed prior to processing the MEMS platform.

6. The method of claim 1, further comprising forming a top cap on the first side of the substrate subsequent to processing the MEMS platform.

7. The method of claim 1, wherein processing the MEMS platform comprises forming a suspended proof mass.

8. The method of claim 1, wherein etching the trench comprises exposing a portion of the MEMS platform to air.

9. The method of claim 1, wherein etching the trench in the second side of the substrate comprises forming a precursor a tether configured to mechanically couple the MEMS structure to a remainder of the substrate.

10. The method of claim, 9, wherein processing the MEMS platform to form the MEMS structure comprises forming the tether from the precursor of the tether.

11. A method for manufacturing a stress-isolated device, comprising:
providing a substrate having a first side and a second side opposite the first side;
forming a precursor of a microelectromechanical systems (MEMS) device on the first side of the substrate, the precursor including at least one MEMS structure;
subsequent to forming the precursor of the MEMS device, etching a trench in the second side of the substrate; and
subsequent to etching the trench, processing the at least one MEMS structure to form a MEMS device, from the precursor, on the first side of the substrate.

12. The method of claim 11, further comprising thinning the second side of the substrate prior to etching the trench.

13. The method of claim 11, further comprising forming a bottom cap on the second side of the substrate subsequent to etching the trench.

14. The method of claim 11, further comprising forming a top cap on the first side of the substrate subsequent to processing the at least one MEMS structure.

15. The method of claim 11, wherein processing the at least one MEMS structure comprises etching a portion of the at least one MEMS structure.
